(19) United States
(12) Patent Application Publication
(10) Pub. No.: US 2012/0152727 A1
(43) Pub. Date: Jun. 21, 2012

(54) Alkali Metal Deposition System

(75) Inventors: Byung Sung Kwak, Portland, OR (US); Stefan Bangert, Steinau (DE); Michael Koenig, Frankfurt (DE); Florian Ries, Westerngrund (DE); Ralf Hofmann, Soquel, CA (US)

(73) Assignee: Applied Materials, Inc., Santa Clara, CA (US)

(21) Appl. No.: 13/301,718

(22) Filed: Nov. 21, 2011

Related U.S. Application Data
(60) Provisional application No. 61/417,108, filed on Nov. 24, 2010.

(51) Int. Cl. C23C 14/34

(52) U.S. Cl. 204/192.15; 204/298.09

(57) ABSTRACT

A deposition system for alkali and alkaline earth metals may include a metal sputter target including cooling channels, a substrate holder configured to hold a substrate facing and parallel to the metal sputter target, and multiple power sources configured to apply energy to a plasma ignited between the substrate and the metal sputter target. The target may have a cover configured to fit over the target material, the cover may include a handle for automated removal and replacement of the cover within the deposition system, and a valve for providing access to the volume between the target material and the cover for pumping, purging or pressurizing the gas within the volume. Sputter gas may include noble gas with an atomic weight less than that of the metal target.

### CROSS-REFERENCE TO RELATED APPLICATIONS

This application claims the benefit of U.S. Provisional Application Ser. No. 61/417,108 filed Nov. 24, 2010, incorporated by reference in its entirety herein.

### FIELD OF THE INVENTION

The present invention relates generally to deposition systems for alkali and alkaline earth metals, and more particularly to high throughput deposition systems.

### BACKGROUND OF THE INVENTION

Prior art alkali and alkaline earth metal deposition systems are known to have low throughput and lack ease of scalability for high throughput and large substrates. There is a need for alkali and alkaline earth metal deposition sources and systems that (1) can be adopted to different substrate formats, including circular, rectangular, etc., (2) may be scaled to accommodate any size of substrate and (3) allow for high throughput deposition—allowing for cost competitive manufacturing of devices such as thin film batteries and electrochromic windows.

### SUMMARY OF THE INVENTION

In general, embodiments of this invention provide high deposition rate sources and systems for deposition of alkali metals and alkaline earth metals which can be adapted to any chamber form factor and are scalable for any size of substrate. These systems may be configured with sputter targets with efficient cooling channels and an air tight, purgeable cover to protect the ambient sensitive targets prior to installation into a deposition chamber under an inert atmosphere. Furthermore, these systems may be configured to make use of: (1) lighter noble gases and/or a mixture of noble gases; and (2) single and multiple power sources, e.g., DC, pulsed DC, RF, RF-DC, pulsed DC-RF, pulsed DC-HF and/or other dual frequency power sources. Yet furthermore, these systems may be configured with a planar substrate parallel to a planar sputter target, the sputter target having a larger surface area (for cluster tool configurations) or larger width (for in-line configurations) than the substrate, thus providing a system which is capable of uniform deposition and scalable to accommodate any shape and size of planar substrate. The targets can also be a cylindrical or annular shape that rotates for high materials utilization applications.

According to aspects of the invention, a deposition system for alkali/alkaline earth metals may comprise: a vacuum chamber; a metal sputter target within the vacuum chamber, the target comprising target material attached to a backing plate including cooling channels; a substrate holder within the vacuum chamber, the holder being configured to hold a substrate facing and parallel to the metal sputter target; and multiple power sources configured to apply energy to a plasma ignited between the substrate and the target material. The cooling channels may be round, rectangular or pyramidal in cross-section. Furthermore, lower temperature capable coolants may be used in the cooling channels to maximize the cooling efficiency, allowing the system to handle high power, high deposition rate and high throughput processing. The single and multiple power sources may include DC, pulsed DC, RF, RF-DC, pulsed DC-RF, pulsed DC-HF and/or other dual frequency power sources. The multiple frequency sources can allow de-convolution of the control of plasma characteristics (self bias, plasma density, ion and electron energies, etc.), so that the higher yielding conditions are reached at a lower power than is otherwise possible with a single power source. For example, a lower frequency power supply can be used to control self bias at the same time a higher frequency supply is used to control ion density. Furthermore, a cover may be used to protect the target material from ambient gases, the cover being removable in the vacuum chamber, the removal being either manual or automated.

According to further aspects of the invention, a method of sputter depositing alkali and alkaline earth metals on a substrate may comprise: igniting a plasma between the substrate and a sputter target within a vacuum chamber, wherein the plasma includes noble gas species and the sputter target comprises target material attached to a backing plate including cooling channels; adding energy to the plasma by multiple power sources, wherein the multiple power sources include a first power source for controlling target material self bias, and a second power source for controlling ion density in the plasma; sputtering target material from the sputter target and depositing the sputtered target material on the substrate, wherein the sputtering is by noble gas species from the plasma and wherein the noble gas species include ions with an atomic weight less than the atomic weight of the target material; and during the sputtering, cooling the sputter target by pumping coolant through the cooling channels in the backing plate. Furthermore, the sputter target may be provided with a cover over the target material, the cover being sealed to the sputter target for protection of the target material from ambient gases, the method including installing the sputter target with the cover in the vacuum chamber and removing the cover from the sputter target in the vacuum chamber. The removal of the cover may be either manual or automated, and when automated may be done under vacuum. The adding energy may include one or more of adding RF-DC, pulsed DC-RF, pulsed DC-HF and/or other dual frequency power sources.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a representation of a wafer based processing tool with an alkali/alkaline earth metal deposition chamber, according to some embodiments of the present invention;

FIGS. 2A and 2B show perspective and cross-sectional views, respectively, of an alkali/alkaline earth metal sputter target with a sealed cover for a wafer-based processing tool, according to some embodiments of the present invention;

FIG. 3 is a representation of an in-line alkali/alkaline earth metal deposition tool, according to some embodiments of the present invention;

FIG. 4 is a representation of a fabrication system with multiple in-line tools, including an alkali/alkaline earth deposition tool, according to some embodiments of the present invention;

FIG. 5 is a schematic block diagram of an example combinatorial plasma deposition chamber, according to some embodiments of the present invention;

FIG. 6 is a first cut-away perspective view of an alkali/alkaline earth metal sputter target with a sealed cover for an in-line processing tool, according to some embodiments of the present invention;

FIG. 7 is a second cut-away perspective view of the alkali/alkaline earth metal sputter target of FIG. 6;

FIG. 8 is a cross-section through the metal target and backing plate of the alkali (alkaline earth) metal sputter target of FIGS. 6 and 7 showing a backing plate with rectangular cooling channels, according to some embodiments of the present invention; and

FIG. 9 is a cross-section through the metal target and backing plate of the alkali metal sputter target of FIGS. 6 and 7 showing a backing plate with pyramidal cooling channels, according to some embodiments of the present invention.

### DETAILED DESCRIPTION

Embodiments of the present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

Sputtering of alkali metals (such as Li, Na, K and Rb), and alkaline earth metals (such as Mg, Ca and Sr) are quite challenging because of their sensitivity to air ambient and due to their low melting temperatures, particularly those metals with lower atomic weight, such as Li, Na and Mg. The challenges come from (1) fabrication and shipment of the sputtering targets where the integrity of the materials must be maintained, (2) installation of the sputtering sources where the reaction with ambient air must be kept to a minimum, and (3) control of the sputtering process, which must keep the metal below its melting temperature to ensure a stable process. All of these factors can limit the sputtering characteristics especially when high deposition rates are required to attain a high throughput manufacturing process.

In addition, the lower atomic weight elements such as Li and Na can suffer from irregular sputtering behaviors when typical noble gases of higher atomic weight, like Ar, are used as the sputtering agent. This irregular sputtering behavior may be “splattering” where the sputtering is not atom-by-atom, but “clusters of atoms” by “clusters of atoms.” Such a situation will adversely affect the deposition uniformity and surface microstructure. To minimize the splattering effect, a lower deposition rate process may be used; however, this leads to adverse manufacturing conditions for throughput.

Some of the concepts of the present invention which address these issues are: (1) use of lighter noble gases such as He and Ne and/or mixture of noble gases such as: He/Ne, He/Ar and Ne/Ar and (2) single and multiple power sources, which may include DC (direct current), pulsed DC, RF (radio frequency), RF-DC, pulsed DC-RF, pulsed DC-HF and/or other dual frequency power sources. The lighter noble gases will lead to more balanced momentum transfer to produce atom-by-atom sputtering while the mixtures may lead to improved sputtering rate. For example, consider the He/Ar mixture for which: (1) the low atomic weight of He reduces the probability of “cluster sputtering” compared with heavier noble gases, (2) He undergoes Penning ionization, providing a high density of sputtering cations, (3) He is relatively inexpensive, particularly when compared with Ne, and (4) Ar increases the sputtering rate. The multiple power sources can lead to better control of sputtering environment (plasma density, sheet voltages, energetics of the plasma species, etc.) to enhance the sputtering behavior and deposition rates. The multiple frequency sources can allow de-convolution of the control of plasma characteristics (self bias, plasma density, ion and electron energies, etc.), so that the higher yielding conditions are reached at lower power than otherwise possible with single power source. For example, a lower frequency power supply can be used to control self bias at the same time a higher frequency supply is used to control ion density. Note that these multiple frequency power sources may both be coupled to the sputter target or the first to the sputter target and the second to the substrate, for example, as described in more detail below. Furthermore, sputtering targets protected from degradation due to exposure to the air and with improved cooling permit high deposition rates of alkali and alkaline earth metals.

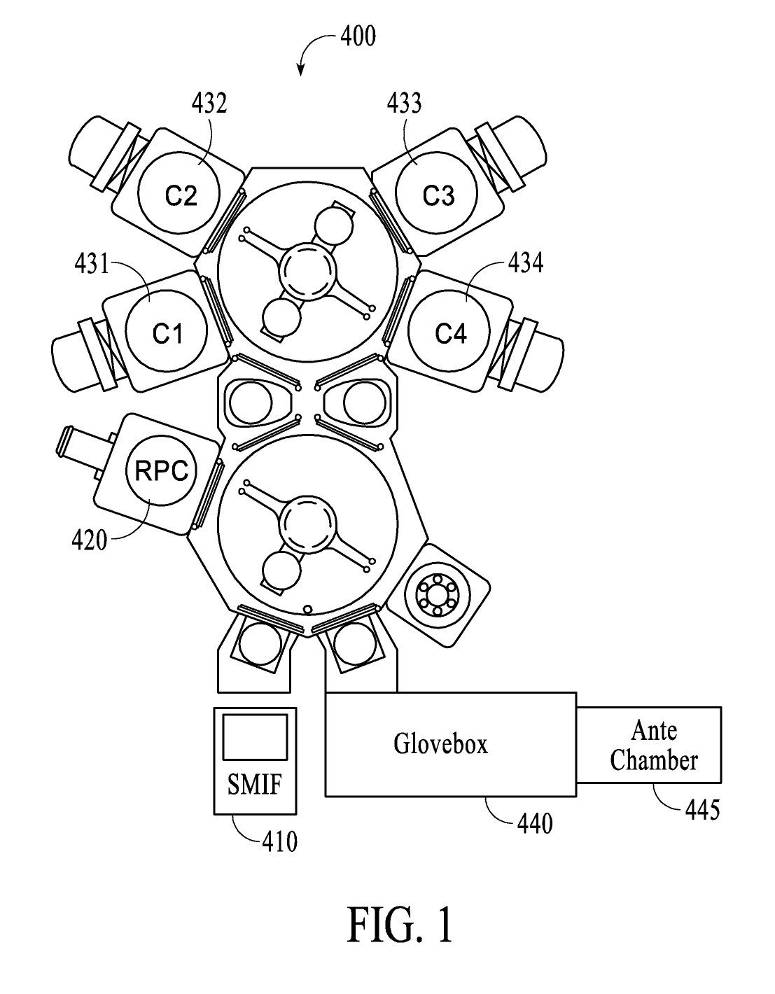

FIG. 1 is a representation of a cluster tool 400 for high throughput sputter deposition of alkali metals and alkaline earth metals on large area substrates, according to some embodiments of the present invention. An example of a suitable cluster tool is Applied Material's Endura™. The example shown in FIG. 1 has a standard mechanical interface (SMIF) 410 to a cluster tool equipped with a reactive plasma clean (RPC) and/or sputter pre-clean (PC) chamber 420 and process chambers C1-C4 (431, 432, 433, and 434, respectively), which may be utilized in the process steps described in more detail below. A glovebox 440 is also attached to the cluster tool. The glovebox can store substrates in an inert environment (for example, under a noble gas such as He, Ne or Ar), which is useful after alkali metal/alkaline earth metal deposition. The ante chamber 445 to the glovebox is a gas exchange chamber (inert gas to air and vice versa) which allows substrates to be transferred in and out of the glovebox without contaminating the inert environment in the glovebox.

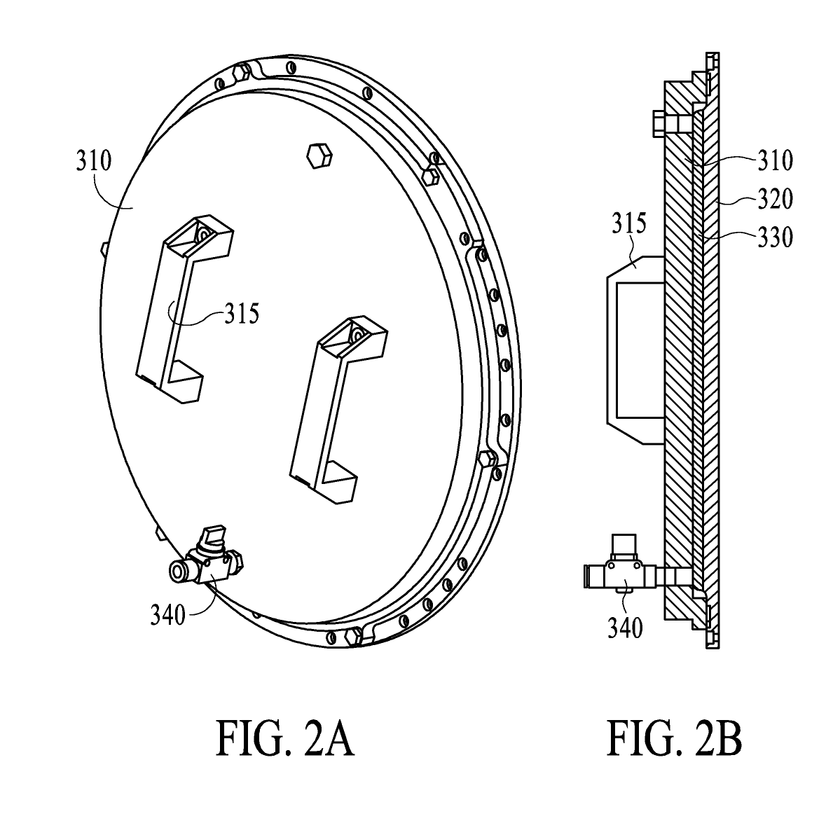

FIGS. 2A and 2B show a cluster tool sputter target design for wafer processing, suitable for high throughput processing of 200 mm wafers, for example—the cluster tool sputter target design is suitable for a wide range of wafer sizes. FIG. 2B is a cross-sectional representation along a diameter of the target, through the valve 340. The design consists of a cover 310 that can be placed on top of the sputtering target 330, with an o-ring seal in between. In addition, the cover consists of valve(s) 340 through which the covered area can be pumped, purged and or pressurized with inert gas for transportation to and from fabrication and manufacturing sites under inert ambient. The covered target can also be placed under additional leak tight packaging, again under inert gas, for further protection of the reactive target material 330. The cover 310 is to be removed during the installation steps. A handle 315 is used for placement and removal of the cover. The design of the cover is such that the target can be installed without removing the cover, so that the exposure of the actual target material 330 to the air ambient is minimized during the installation. The removal of the cover can be automated where the chamber is closed with the cover in place, then under vacuum, the cover is removed to a non sputtering zone adjacent to the target area. Note that, if necessary, the process chamber may be enlarged/elongated to allow cover removal within the chamber. In a manual removal of the cover, standard precautionary steps can be taken to minimize exposure of the target to the ambient. However, experience on an R&D inline system indicates that these standard precautionary measures may not be necessary as the cover allows very minimal exposure to the ambient. Furthermore, a sputter clean may be sufficient to clean away any surface reacted layers. The sputter target backing plate 320 may be in contact with a reservoir of coolant for enabling efficient removal of heat from the target material 330.

The chambers C1-C4 can be configured for process steps for manufacturing thin film battery devices which may include: deposition of a cathode layer (e.g. LiCoO₂ by RF sputtering); deposition of an electrolyte layer (e.g. Li₃PO₄ by RF sputtering in N₂); and deposition of an alkali metal or alkaline earth metal. See U.S. Patent Application Publication No. 2009/0148764 for examples of fabrication process flows for thin film batteries. Furthermore, the chambers C1-C4 can be configured for process steps for manufacturing electrochromic windows. See U.S. Patent Application Publication No. 2009/0304912 for examples of fabrication process flows for electrochromic windows.

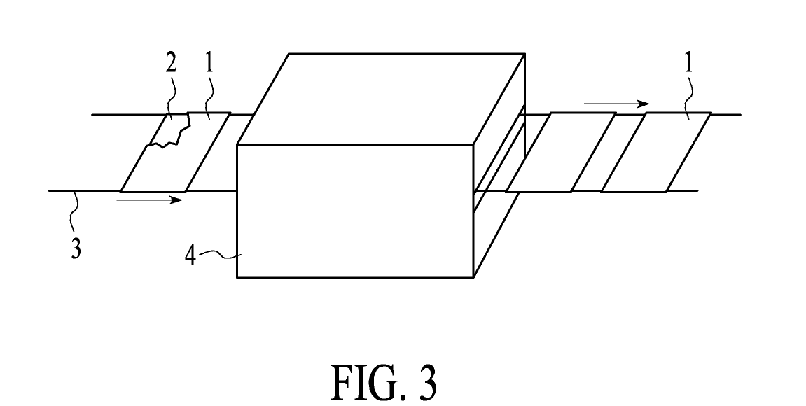

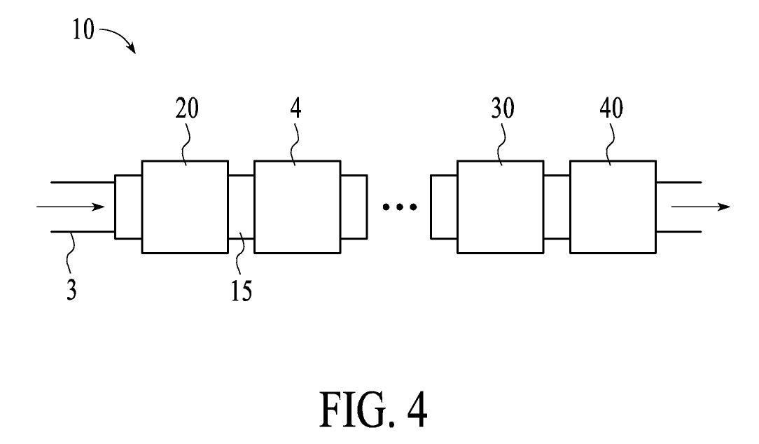

FIG. 3 is a representation of an in-line tool for high throughput sputter deposition of alkali and alkaline earth metals on large area substrates, according to some embodiments of the present invention. A substrate holder 1 containing a large area substrate 2 (the substrate holder is shown partially cut-away so that the substrate can be seen) is mounted on a track 3, or equivalent device, for moving the holder and substrate through a sputter deposition tool 4, as indicated. The in-line tool may be configured for substrates oriented either horizontally or vertically. For ease of illustration, only one processing tool is shown; however, multiple processing tools may be used on the same in-line processing system. See FIG. 4. Suitable in-line platforms for processing tool 4 are Applied Material's Aton™ and New Aristo™.

FIG. 4 shows a representation of a fabrication system 10 with multiple in-line tools 4, 20, 30, 40, etc., including an alkali deposition tool 4, according to some embodiments of the present invention. The in-line tools may include pre- and post-conditioning chambers. For example, tool 20 may be a pump down chamber for establishing a vacuum prior to the substrate moving through a vacuum airlock 15 into alkali metal deposition tool 4. Furthermore, the in-line tools may include process tools, such as deposition tools and patterning tools, for manufacturing devices such as thin film batteries and electrochromic windows. Some or all of these tools may be vacuum tools separated by vacuum airlocks 15. Note that the order of process tools and specific process tools in the process line will be determined by the particular fabrication method being used.

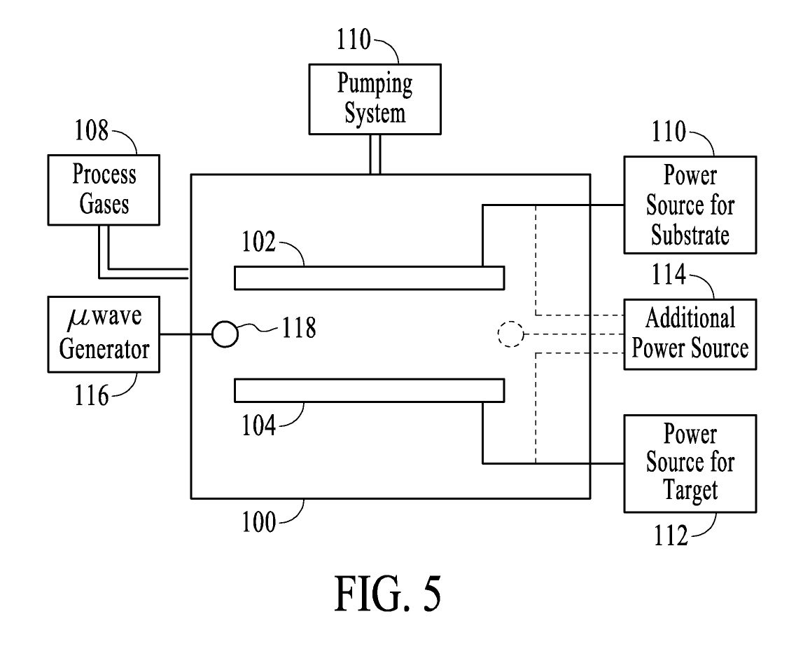

FIG. 5 shows an example of a combinatorial plasma deposition chamber for deposition of an alkali metal or alkaline earth metal according to some embodiments of the invention. The system includes a chamber 100 housing a sputter target 104 and the substrate holder 102 for holding a substrate. Pumping system 106 is connected to chamber 100 for controlling a pressure therein, and process gases 108 represents sources of gases supplied to chamber 100 used in the deposition process. According to aspects of the invention, combinatorial plasma is achieved by coupling appropriate plasma power sources 110 and 112 to both the substrate (in the substrate holder 102) and target 104. An additional power source 114 may also be applied to the target 104, or the substrate or be used for transferring energy directly to the plasma, depending on the type of plasma deposition technique. Furthermore, a microwave generator 116 may provide microwave energy to a plasma within the chamber through the antenna 118. Microwave energy may be provided to the plasma in many other ways, as is known to those skilled in the art. The schematic is not meant to define orientation of the chamber with respect to gravity, i.e., the chamber may be oriented such that sputtering may be down, up or sideways, for example.

Depending on the type of plasma deposition technique used, substrate power source 110 can be a DC source, a pulsed DC (pDC) source, a RF source, etc. Target power source 112 can be DC, pDC, RF, etc., and any combination thereof. Additional power source 114 can be pDC, RF, microwave, a remote plasma source, etc.

Although the above provides the range of possible power sources, some specific examples of combinations of power source to target 104 plus power source to substrate for alkali metal/alkaline earth metal deposition are: (1) DC, pDC or RF at the target 104 plus HF or microwave plasma enhancement; (2) DC, pDC or RF at the target plus HF/RF substrate bias; and (3) DC, pDC or RF at the target 104 plus HF or microwave plasma plus HF/RF substrate bias. The nomenclature HF/RF is used to indicate the potential need for power sources of two different frequencies, where the frequencies are sufficiently different to avoid any interference. Although, the frequencies of the RF at the target 104 and at the substrate may be the same providing they are locked in phase. Furthermore, the substrate itself can be biased to modulate the plasma-substrate interactions. In particular, multiple frequency sources can allow deconvolution of the control of plasma characteristics (self bias, plasma density, ion and electron energies, etc.), so that the high yielding conditions are reached at lower power than otherwise possible with single power source.

Furthermore, some specific examples of combinations of power sources to target 104 are: (1) RF1 at the target plus RF2 at the target, where the frequencies of RF1 and RF2 are sufficiently different to avoid interference; (2) DC at the target plus RF at the target; and (3) pDC at the target plus RF at the target. As described above, multiple frequency sources can allow deconvolution of the control of plasma characteristics (self bias, plasma density, ion and electron energies, etc.), so that the high yielding conditions are reached at lower power than otherwise possible with a single power source. Furthermore, increased ion density in the plasma, due to a higher frequency power supply, may enhance atom-by-atom deposition.

Furthermore, the planar substrate and target in FIG. 5 are configured parallel to each other. This parallel configuration allows the deposition system to be scaled for any size of planar substrate while maintaining the same deposition characteristics. Note, as discussed above, that the size of the substrate and the target are roughly matched, with the target area (cluster tool) or width (in-line tool) being larger than that of the substrate so as to avoid target edge effects in the deposition uniformity on the substrates.

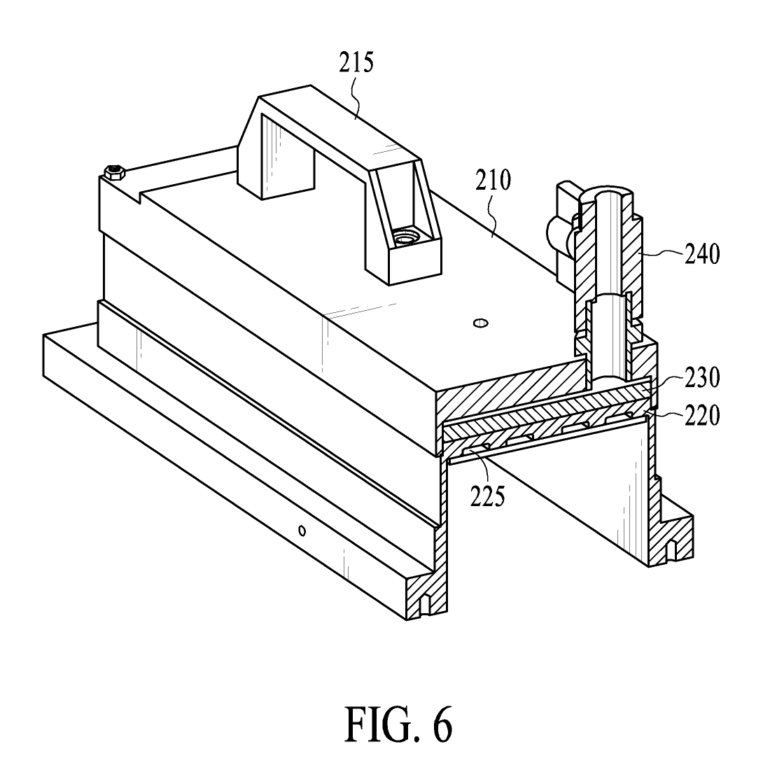

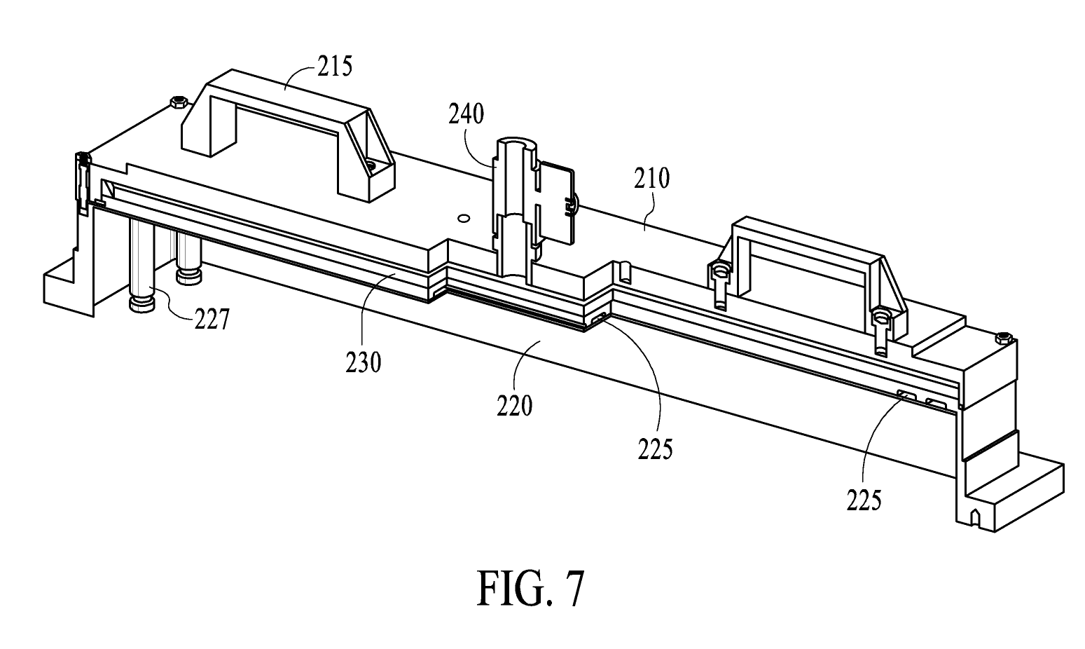

FIGS. 6 and 7 show the linear sputtering target design for an inline system. As can be seen, the design consists of a cover 210 that can be placed on top of the sputtering target, making an o-ring seal. In addition, the cover consists of valve(s) 240 through which the covered area can be pumped, purged and or pressurized with inert gas for transportation to and from fabrication and manufacturing sites under inert ambient. The covered target can also be placed under additional leak tight packaging, again under inert gas, for further protection of the reactive target material 230. The cover 210 is to be removed during the installation steps. A handle 215 is used for placement and removal of the cover.

The design of the cover is such that the target can be installed without removing the cover, so that the exposure of the actual target material 230 to the air ambient is minimized during the installation. The removal of the cover can be automated where the chamber is closed with the cover in place, then under vacuum, the cover is removed to a non sputtering zone adjacent to the target area. In a manual removal of the cover, standard precautionary steps can be taken to minimize exposure of the target to the ambient. However, experience on an R&D inline system indicates that these standard precautionary measures may not be necessary as the cover allows very minimal exposure to the ambient. Furthermore, a sputter clean may be sufficient to clean away any surface reacted layers.

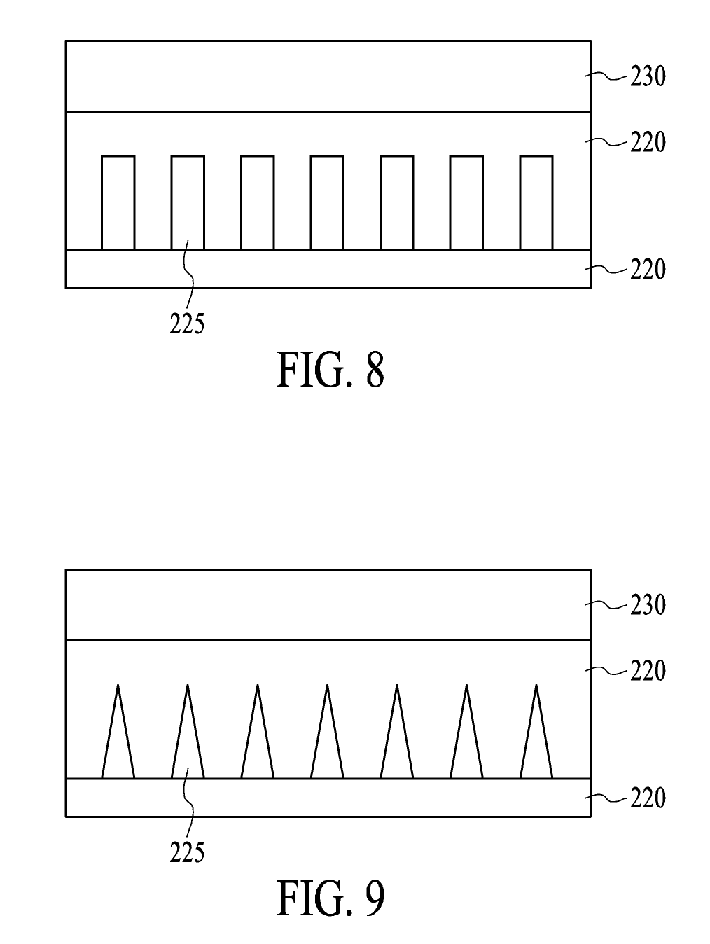

The sputter target backing plate 220 includes cooling channels 225 for enabling efficient removal of heat from the target material 230, as described in more detail with reference to FIGS. 8 & 9. A coolant is pumped into the target backing plate 220 through cooling conduits 227, which connect to the cooling channels 225. The cooling channels 225 and conduits 227, along with a pump and cooling system (not shown in figure), are configured to form a cooling circuit through which coolant may be pumped.

FIGS. 8 and 9 show enlarged views of the backing plate, onto which the target material is bonded. An important aspect of the design is in the cooling channel of the backing plate, where the surface area of the backing plate is increased to increase thermal conduction between the backing plate and the cooling medium. This increased thermal conduction should help lower the temperature of the target which will allow using higher sputtering power densities for higher sputtering and deposition rates. Additionally, the cooling medium can be maintained at a temperature below zero degrees Celsius by using, for example, glycol based compounds, and thereby further enhancing the thermal conductivity of the whole system and the robustness of the system against thermal constraints of deposition rate processes.

FIG. 8 shows a cross-section through the metal target and backing plate of the alkali metal/alkaline earth metal sputter target of FIGS. 6 and 7 showing a backing plate with rectangular cooling channels. FIG. 9 shows a cross-section through the metal target and backing plate of the alkali metal/alkaline earth metal sputter target of FIGS. 6 and 7 showing a backing plate with pyramidal cooling channels. These particular shapes for cooling channels are provided as examples; other cooling channel shapes may also be used to effect. Furthermore, these cooling channel configurations may also be utilized with the backing plate of FIGS. 2A and 2B.

A method of sputter depositing alkali and alkaline earth metals on a substrate may comprise: igniting a plasma between the substrate and a sputter target within a vacuum chamber, wherein the plasma includes noble gas species and the sputter target comprises target material attached to a backing plate including cooling channels; adding energy to the plasma by multiple power sources, wherein the multiple power sources include a first power source for controlling target material self bias, and a second power source for controlling ion density in the plasma; sputtering target material from the sputter target and depositing the sputtered target material on the substrate, wherein the sputtering is by noble gas species from the plasma and wherein the noble gas species include ions with an atomic weight less than the atomic weight of the target material; and during the sputtering, cooling the sputter target by pumping coolant through the cooling channels in the backing plate. Furthermore, the sputter target may be provided with a cover over the target material, the cover being sealed to the sputter target for protection of the target material from ambient gases, the method including installing the sputter target with the cover in the vacuum chamber and removing the cover from the sputter target in the vacuum chamber. The removal of the cover may be either manual or automated, and when automated may be done under vacuum. The adding energy may include one or more of adding RF-DC, pulsed DC-RF, pulsed DC-HF and/or other dual frequency power sources.

Although the targets are described herein as planar targets, the targets can also be cylindrical or annular shaped targets that are rotated for high materials utilization—in either cluster tool or in-line configurations.

Although the present invention has been particularly described with reference to certain embodiments thereof, it should be readily apparent to those of ordinary skill in the art that changes and modifications in the form and details may be made without departing from the spirit and scope of the invention.

What is claimed is:

1. A deposition system for alkali and alkaline earth metals comprising:
a vacuum chamber;
a metal sputter target within said vacuum chamber, said target comprising target material attached to a backing plate including cooling channels;
a substrate holder within said vacuum chamber, said holder being configured to hold a substrate facing and parallel to said metal sputter target; and
multiple power sources configured to apply energy to a plasma ignited between said substrate and said target material, said multiple power sources including a first power source for controlling target material self bias, and a second power source for controlling ion density in said plasma;
wherein said target material is an alkali metal or alkaline earth metal.

2. The deposition system of claim 1, wherein said cooling channels are round, rectangular or pyramidal in cross-section.

3. The deposition system of claim 1, further comprising a pump and cooling unit configured to circulate a coolant through said cooling channels.

4. The deposition system of claim 3, wherein said coolant is provided to said cooling channels at a temperature of less than zero degrees Celsius.

5. The deposition system of claim 1, further comprising a cover configured to fit over said target material, said cover and said metal sputter target being configured to form a seal there between.

6. The deposition system of claim 5, wherein said cover includes a handle for removal and replacement of said cover within said deposition system, said deposition system being configured to accommodate automated removal of said cover and storage of said cover in a non-sputtering zone adjacent to said metal sputter target.

7. The deposition system of claim 5, wherein said cover includes a valve for providing access to the sealed volume between said target material and said cover for pumping, purging or pressurizing the gas in said sealed volume.

8. The deposition system of claim 1, wherein said multiple power sources include a first radio frequency power source coupled to said target and a second radio frequency power source coupled to said target, said first and second radio frequency power sources being configured to provide different frequencies to said metal sputter target.

9. The deposition system of claim 8, wherein said first radio frequency power source controls target material self bias, and said second radio frequency power source controls ion density in said plasma.

10. The deposition system of claim 1, wherein said multiple power sources include a radio frequency power source coupled to said target and a direct current power source coupled to said target.

11. The deposition system of claim 1, wherein said multiple power sources include a radio frequency power source coupled to said target and a pulsed direct current power source coupled to said target.

12. The deposition system of claim 1, wherein said deposition system is configured for integration into a cluster tool.

13. The deposition system of claim 12, wherein the surface area of said target material is larger than the substrate area.

14. The deposition system of claim 1, wherein said deposition system is configured for integration into an in-line tool.

15. The deposition system of claim 14, wherein the width of said target material is greater than the substrate width.

16. The deposition system of claim 1, further comprising a process gas supply coupled to said vacuum chamber, said process gas supply including a supply of noble gas, said noble gas being chosen with an atomic weight less than the atomic weight of said target material.

17. The deposition system of claim 1, further comprising a process gas supply coupled to said vacuum chamber, said process gas supply including a supply of noble gases, said noble gases including a first noble gas with an atomic weight less than the atomic weight of said target material and a second noble gas with an atomic weight greater than the atomic weight of said target material.

18. The deposition system of claim 17, wherein said first noble gas is Helium, said second noble gas is Argon and said target material is Lithium.

19. A method of sputter depositing alkali and alkaline earth metals on a substrate comprising:
igniting a plasma between said substrate and a sputter target within a vacuum chamber, wherein said plasma includes noble gas species and said sputter target comprises target material attached to a backing plate including cooling channels;
adding energy to said plasma by multiple power sources, wherein said multiple power sources include a first power source for controlling target material self bias, and a second power source for controlling ion density in said plasma;
sputtering target material from said sputter target and depositing the sputtered target material on said substrate, wherein said sputtering is by noble gas species from said plasma and wherein said noble gas species include ions with an atomic weight less than the atomic weight of said target material; and
during said sputtering, cooling said sputter target by pumping coolant through said cooling channels in said backing plate;
wherein said target material is an alkali metal or alkaline earth metal.

20. The method of claim 19, further comprising:
providing said sputter target with a cover over said target material, said cover being sealed to said sputter target for protection of said target material from ambient gases;
installing said sputter target with said cover in said vacuum chamber; and
removing said cover from said sputter target in said vacuum chamber.

21. The method of claim 20, further comprising pumping down said vacuum chamber after said installing, and wherein said removing is automated under vacuum in said vacuum chamber.
